(19) United States
(12) Patent Application Publication
(10) Pub. No.: US 2011/0240989 A1
(43) Pub. Date: Oct. 6, 2011

(54) TRANSPARENT CONDUCTIVE FILM AND PHOTOELECTRIC CONVERION ELEMENT

(75) Inventors: Masaaki Sekine, Miyagi (JP); Kyoko Sakurai, Miyagi (JP); Seiichi Onodera, Miyagi (JP)

(73) Assignee: Sony Corporation, Tokyo (JP)

(21) Appl. No.: 13/069,669

(22) Filed: Mar. 23, 2011

(30) Foreign Application Priority Data
Apr. 6, 2010 (JP) 2010-087549

(51) Int. Cl. H01L 29/12; H01B 5/00

(52) U.S. Cl. 257/43; 174/126.2; 257/E29.068

(57) ABSTRACT

A transparent conductive film includes: a first conductor layer formed of a first transparent conducting oxide having a first specific resistance; and a second conductor layer that is laminated on the first conductor layer, has a second specific resistance that is equal to or larger than the first specific resistance and equal to or smaller than 1*10⁶ Ω*cm, and is formed of a second transparent conducting oxide including titanium.

### BACKGROUND OF THE INVENTION

1. Field of the Invention

The present invention relates to a transparent conductive film having corrosion resistance and a photoelectric conversion element including the transparent conductive film.

2. Description of the Related Art

In recent years, dye-sensitized solar cells as one of photoelectric conversion elements are being developed. A dye-sensitized solar cell includes a semiconductor layer that supports a pigment, a negative electrode that comes into contact with the semiconductor layer, an electrolyte, and a positive electrode opposing the semiconductor layer with the electrolyte interposed between the positive electrode and the electrolyte. The pigment emits electrons by light entering the semiconductor layer, and the emitted electrons are transported to the negative electrode via the semiconductor layer. The negative electrode and the positive electrode are connected to an external circuit, and the electrons that have reached the positive electrode via the external circuit are caused to return to the pigment by the electrolyte. By repeating such a cycle, electric energy can be extracted in the external circuit.

In the dye-sensitized solar cell, a system in which a negative electrode is formed by a transparent conductive film and sunlight is caused to enter a semiconductor layer from the negative electrode side is typically adopted (see, for example, Japanese Patent Application Laid-open No. 2005-19205 and Japanese Patent Application Laid-open No. 2006-66278). In this case, for efficiently extracting electrons emitted from a pigment, the negative electrode that is in contact with the semiconductor layer is required to have a high optical transmittance and low electrical resistance. On the other hand, for suppressing lowering of a temporal conversion efficiency, the constituent material of the negative electrode is required to have durability with respect to an electrolytic solution. Therefore, a fluorine-doped tin oxide (FTO) is widely used for the transparent conductive film constituting the negative electrode.

### SUMMARY OF THE INVENTION

However, since the FTO film has a higher resistivity than other transparent conductive oxides such as a zinc oxide (ZnO) and an indium tin oxide (ITO), there has been a limit in improving an incident photon-to-current conversion efficiency. On the other hand, since ITO films and zinc oxide-based transparent conductive films have poor acid resistance, there has been a problem in applying them to solar cells that use an electrolyte having strong corrosiveness.

In view of the circumstances as described above, there is a need for a transparent conductive film having transparency, conductivity, and corrosion resistance and a photoelectric conversion element including the transparent conductive film.

According to an embodiment of the present invention, there is provided a transparent conductive film including a first conductor layer and a second conductor layer.

The first conductor layer is formed of a first transparent conducting oxide having a first specific resistance.

The second conductor layer is laminated on the first conductor layer, has a second specific resistance that is equal to or larger than the first specific resistance and equal to or smaller than 1*10⁶ Ω*cm, and is formed of a second transparent conducting oxide including titanium.

The transparent conductive film is formed by a multilayer film constituted of the first conductor layer and the second conductor layer having a higher resistance than the first conductor layer. Since the second conductor layer has a specific resistance of 1*10⁶ Ω*cm or less, an increase of the sheet resistance of the entire film is suppressed and can be made about the same level as the sheet resistance of the first conductor layer alone. Moreover, lowering of transparency is also suppressed. In addition, since a titanium oxide has excellent durability with respect to acid, by covering the first conductor layer with the second conductor layer that includes a titanium oxide, it becomes possible to effectively protect the first conductor layer from acid.

An increase of a sheet resistance with respect to a sheet resistance of the first conductor layer alone, which is obtained after the second conductor layer is laminated, is 10Ω/□ or less. With this structure, the protective effect of the first conductor layer can be obtained without impairing low resistance characteristics.

The first transparent conducting oxide may be a tin oxide including indium (ITO). With this structure, the resistance of the first conductor layer can be easily lowered.

The transparent conductive film may further include a third conductor layer. The third conductor layer is provided inside the first conductor layer, has a third specific resistance smaller than the first specific resistance, and is formed in a lattice. A metal layer can be used for the third conductor layer. With this structure, the sheet resistance of the entire transparent conductive film can be additionally lowered.

According to an embodiment of the present invention, there is provided a photoelectric conversion element including a first electrode, an oxide semiconductor layer, a second electrode, and an electrolyte layer.

The first electrode includes a first conductor layer and a second conductor layer. The first conductor layer is formed of a first transparent conducting oxide having a first specific resistance. The second conductor layer is laminated on the first conductor layer, has a second specific resistance that is equal to or larger than the first specific resistance and equal to or smaller than 1*10⁶ Ω*cm, and is formed of a second transparent conducting oxide including titanium.

The oxide semiconductor layer comes into contact with the second conductor layer and supports a photosensitization pigment.

The second electrode is opposed to the oxide semiconductor layer.

The electrolyte layer is provided between the oxide semiconductor layer and the second electrode.

In the photoelectric conversion element, the first electrode has transparency, conductivity, and sufficient durability with respect to an electrolyte with a strong oxidation nature. Therefore, with the conversion element, it is possible to improve the incident photon-to-current conversion efficiency by a low resistance of the negative electrode and prevent the incident photon-to-current conversion efficiency from being lowered with time due to corrosion prevention of the negative electrode.

The oxide semiconductor layer may be formed of a porous titanium oxide. With this structure, since the oxide semiconductor layer and the second conductor layer are formed of the same type of material, a transportation efficiency of electrons from the oxide semiconductor layer to the first electrode can be enhanced and the incident photon-to-current conversion efficiency can be improved.

According to the embodiments of the present invention, a transparent conductive film having excellent transparency, conductivity, and corrosion resistance can be obtained. Moreover, a photoelectric conversion element with which an incident photon-to-current conversion efficiency can be improved can be obtained.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a schematic cross-sectional diagram of a photoelectric conversion element according to a first embodiment of the present invention;

FIG. 2 are sample diagrams for explaining corrosion resistance of a transparent conductive film according to the first embodiment of the present invention, and a diagram showing experimental results;

FIG. 3 is a schematic cross-sectional diagram of a photoelectric conversion element according to a second embodiment of the present invention; and

FIG. 4 is a schematic cross-sectional diagram of a printed circuit board according to a modified example of the present invention.

### DESCRIPTION OF PREFERRED EMBODIMENTS

Hereinafter, embodiments of the present invention will be described with reference to the drawings.

### First Embodiment

### Photoelectric Conversion Element

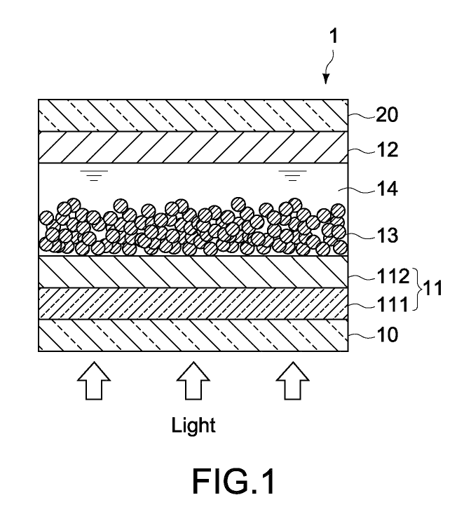

FIG. 1 is a schematic cross-sectional diagram of a photoelectric conversion element according to a first embodiment of the present invention. Hereinafter, a photoelectric conversion element 1 of this embodiment will be described.

The photoelectric conversion element 1 of this embodiment is constituted of a dye-sensitized solar cell. The photoelectric conversion element 1 includes a negative electrode 11 as a collective electrode, a positive electrode 12 as an antipole, an oxide semiconductor layer 13, and an electrolyte layer 14. The negative electrode 11 and the positive electrode 12 are connected to a negative electrode and a positive electrode of an external circuit (load) (not shown). The oxide semiconductor layer 13 is in contact with the negative electrode 11 and formed of a porous titanium oxide. The oxide semiconductor layer 13 supports a pigment whose electrons are excited by visible light irradiated onto the pigment, for example. The electrolyte layer 14 is interposed between the oxide semiconductor layer 13 and the positive electrode 12 and formed of an oxidation-reduction material constituted of a combination of, for example, metallic iodide and iodine.

The negative electrode 11 is formed on a transparent substrate 10 and constituted of a transparent conductive film that is structured by a multilayer film constituted of a first conductor layer 111 and a second conductor layer 112 as will be described later. The positive electrode 12 is formed on a transparent substrate 20 and constituted of a metallic film formed of, for example, silver. Alternatively, the positive electrode 12 may be constituted of a transparent conductive film. The transparent substrates 10 and 20 are formed of a resin film having optical transparency, such as PET (polyethylene terephthalate), PEN (polyethylene naphthalate), and PC (polycarbonate), a glass substrate, or the like.

### (Transparent Conductive Film)

Next, the transparent conductive film constituting the negative electrode 11 will specifically be described.

The negative electrode 11 is structured by a multilayer film constituted of the first conductor layer 111 and the second conductor layer 112. The first conductor layer 111 and the second conductor layer 112 are formed on the transparent substrate 10 in the stated order.

The first conductor layer 111 is formed of a transparent conducting oxide and formed of ITO in this embodiment. In addition to ITO, other transparent conducting oxides such as SnO and ZnO are also applicable. Accordingly, the resistance of the negative electrode 11 can be lowered with ease. Further, AZO, GZO, IZO, IGZO, and the like that are doped with aluminum, gallium, indium, and the like may be used as a ZnO-based transparent conducting oxide.

The specific resistance of the first conductor layer 111 is smaller the better in view of the incident photon-to-current conversion efficiency of the photoelectric conversion element 1. In this embodiment, the first conductor layer 111 has a specific resistance of, for example, 5*10⁻³ Ω*cm or less. The thickness of the first conductor layer 111 is not particularly limited and is, for example, 150 nm to 400 nm.

The second conductor layer 112 is formed of a transparent conducting oxide and formed on the first conductor layer 111. The second conductor layer 112 has a function as a protective layer for protecting the first conductor layer 111 from a corrosion due to the first conductor layer 111 being in contact with the electrolyte layer 14. Therefore, the second conductor layer 112 is formed of a transparent conducting oxide having acid resistance. In this embodiment, the second conductor layer 112 is formed of a transparent conducting oxide including a titanium oxide (TiOx). The second conductor layer 112 is constituted of a denser film than the oxide semiconductor layer 13.

Here, the transparent conducting oxide including a titanium oxide may include metallic oxides other than a titanium oxide. Examples of other metallic oxides include oxides of zirconium (Zr), niobium (Nb), cerium (Ce), tungsten (W), silicon (Si), aluminum (Al), tin (Sn), zinc (Zn), magnesium (Mg), bismuth (Bi), manganese (Mn), yttrium (Y), tantalum (Ta), lanthanum (La), and strontium (Sr).

The second conductor layer 112 has a specific resistance (second specific resistance) that is equal to or larger than the specific resistance of the first conductor layer 111 (first specific resistance). As described above, the second conductor layer 112 is formed of a transparent conducting oxide having a higher resistance than the first conductor layer 111. The specific resistance of the second conductor layer 112 is 1*10⁶ Ω*cm or less. Accordingly, an increase of the resistance of the negative electrode 11 can be suppressed.

The thickness of the second conductor layer 112 is, for example, 5 nm or more and 500 nm or less. With a thickness smaller than 5 nm, the acid resistance of the second conductor layer 112 becomes difficult to be secured. Further, with a thickness exceeding 500 nm, there is a fear that the optical transmittance of the transparent conductive film (negative electrode 11) may decrease.

In general, the specific resistance of the transparent conducting oxide such as a titanium oxide varies depending on a valence of oxygen (oxidation degree). Therefore, by adjusting the valence of oxygen, the specific resistance of the second conductor layer 112 can be controlled.

In this embodiment, the specific resistance and thickness of the second conductor layer 112 are determined such that an increase of a sheet resistance with respect to a sheet resistance of the first conductor layer 111 alone, which is obtained after the second conductor layer 112 is laminated, becomes 10Ω/□ or less. Accordingly, the protective effect of the second conductor layer 112 on the first conductor layer 111 can be obtained without impairing the low resistance characteristics of the first conductor layer 111.

The transmittance of the transparent conductive film (negative electrode 11) with respect to visible light is higher the better in view of the incident photon-to-current conversion efficiency of the photoelectric conversion element 1. In this embodiment, the transparent conductive film (negative electrode 11) has a visible light transmittance of 70% or more. The thickness of each of the first conductor layer 111 and the second conductor layer 112 is set as appropriate so that the high transmittance characteristics described above can be obtained.

Though the first conductor layer 111 and the second conductor layer 112 are formed by a sputtering method, the method is of course not limited thereto, and other thin film forming methods such as a vacuum vapor deposition method and an ion plating method are also applicable.

### (Operation of Photoelectric Conversion Element)

In the photoelectric conversion element 1 of this embodiment, light such as sunlight and artificial light enters the oxide semiconductor layer 13 from the negative electrode 11 side. When the oxide semiconductor layer 13 is irradiated with light, electrons in the pigment transit from a basal state to an excited state to be emitted from the pigment. The oxide semiconductor layer 13 transports the electrons emitted from the pigment to the negative electrode 11 so that the electrons are supplied to the external circuit from the negative electrode. The electrons that have passed the external circuit are transported to the positive electrode and returned to the pigment on the oxide semiconductor layer 13 after undergoing an oxidation-reduction reaction with the electrolyte layer 14. By repeating such a cycle, electric energy is extracted in the external circuit.

In this embodiment, the negative electrode 11 is structured by a multilayer film constituted of the first conductor layer 111 and the second conductor layer 112. The second conductor layer 112 is formed of a transparent conducting oxide having a higher resistance than the first conductor layer 111. By setting the specific resistance of the second conductor layer 112 to be 1*10⁶ Ω*cm or less, an increase of the sheet resistance of the entire film can be suppressed, and the sheet resistance can be made about the same level as that of the first conductor layer 111 alone. As a result, since low resistance characteristics can be secured while maintaining the transparency of the negative electrode 11, the incident photon-to-current conversion efficiency can be prevented from being lowered.

The inventors of the present invention sequentially formed an ITO layer and a TiOx layer on a PEN substrate having a thickness of 125 μm by a sputtering method and measured a sheet resistance and total light transmittance of the formed multilayer film. The results are shown in Table 1.

TABLE 1

| | | Experimental | Experimental |
|---|---|---|---|
| | | Example 1 | Example 2 |
| High- | TiOx film | 50 nm | 100 nm |
| resistance | thickness | | |
| conductive | | | |
| film | | | |
| Transparent | ITO film | 200 nm | 200 nm |
| conductive | thickness | | |
| film | | | |
| Transparent | PEN thickness | 125 μm | 125 μm |
| substrate | | | |

| | | |
|---|---|---|
| Sheet resistance (Ω/□) of | 14.02 | 15.33 |
| ITO alone | | |
| Sheet resistance (Ω/□) | 15.06 | 13.93 |
| after ITO/TiOx are | | |
| laminated | | |
| Total light transmittance | 72.6 | 70.5 |
| (%) after ITO/TiOx are | | |
| laminated | | |

In Experimental Example 1, the thickness of the ITO layer was 200 nm and the thickness of the TiOx layer was 50 nm. The sheet resistance of the ITO layer alone was 14.02Ω/□, the sheet resistance of the multilayer film was 15.06Ω/□, and the total light transmittance of the multilayer film was 72.6%. Moreover, in Experimental Example 2, the thickness of the ITO layer was 200 nm and the thickness of the TiOx layer was 100 nm. The sheet resistance of the ITO layer alone was 15.33Ω/□, the sheet resistance of the multilayer film was 13.93Ω/□, and the total light transmittance of the multilayer film was 70.5%. It should be noted that a four probe method was adopted for measuring the sheet resistance.

The specific resistance of ITO was 3*10⁻⁴ Ω*cm. The sheet resistance of the TiOx layer alone was as high as 10⁷Ω/□ with the thickness of 50 nm, and the specific resistance was 5*10² Ω*cm. According to Experimental Example 1, the sheet resistance of the multilayer film increased only about 1Ω/□ with respect to the sheet resistance of the ITO layer alone, and the optical transmittance was maintained at 70% or more. Moreover, according to Experimental Example 2, since the thickness of the TiOx layer has increased as compared to Experimental Example 1, a slight decrease of the transmittance was recognized. However, it was confirmed that the sheet resistance of the multilayer film was lower than that of the ITO layer alone, and a value that is about the same level as the sheet resistance of the ITO layer alone can be obtained even when considering an error.

On the other hand, according to this embodiment, since the first conductor layer 111 is covered by the second conductor layer 112 having acid resistance, it is possible to prevent the first conductor layer 111 formed of the transparent conducting oxide with poor acid resistance, such as ITO, from coming into contact with the electrolyte layer 14 having a strong oxidation nature. As a result, the first conductor layer 111 can be protected from a corrosion, and the incident photon-to-current conversion efficiency can be prevented from lowering due to the corrosion of the first conductor layer 111.

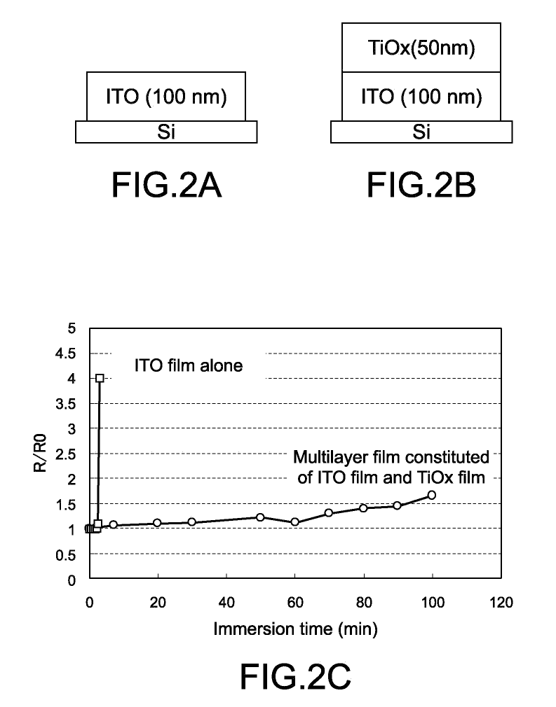

A resistance value obtained at a time a conductive film sample is immersed in strong hydrochloric acid (aqueous solution containing 70% of hydrochloric acid (pH 0.7)) at room temperature was measured. As the conductive film sample, an ITO monolayer film that is formed on a silicon substrate and has a thickness of 100 nm as shown in FIG. 2A and a multilayer film constituted of an ITO layer that is formed on a silicon substrate and has a thickness of 100 nm and a TiOx layer having a thickness of 50 nm as shown in FIG. 2B were used. The experimental results are shown in FIG. 2C. In FIG. 2C, the abscissa axis represents an immersion time and the ordinate axis represents a relative ratio of a resistance value obtained after the immersion with respect to the initial resistance value of the conductive film sample. As is apparent from FIG. 2C, the ITO monolayer film is rapidly corroded due to the film being in contact with the strong hydrochloric acid, and the resistance value increases exponentially. On the contrary, in the multilayer film in which the ITO layer is covered by the TiOx layer, it was confirmed that the increase of the resistance value due to a corrosion is extremely gradual and the multilayer film has durability with respect to the strong hydrochloric acid. Therefore, according to the photoelectric conversion element 1 that includes the negative electrode 11 constituted of the transparent conductive film of this embodiment, it is possible to enhance durability with respect to the electrolyte layer 14 and secure stable photoelectric conversion characteristics.

Furthermore, according to this embodiment, an interface of the negative electrode 11 that comes into contact with the oxide semiconductor layer 13 is constituted of the second conductor layer 112 including a titanium oxide. Accordingly, the oxide semiconductor layer 13 and the contact interface between the oxide semiconductor layer 13 and the negative electrode 11 are formed of the same type of semiconductor material. As a result, electron conductance bands among the layers are approximated, and an electron transportation efficiency from the oxide semiconductor layer 13 to the negative electrode 11 is promoted, thus leading to an increase of the incident photon-to-current conversion efficiency.

Also in this embodiment, the second conductor layer 112 has a higher resistance than the first conductor layer 111 and is constituted of a denser film than the oxide semiconductor layer 13. Therefore, because the second conductor layer 112 is interposed between the first conductor layer 111 and the oxide semiconductor layer 13, a so-called reverse electron reaction in which electrons flow backward from the negative electrode 11 to the oxide semiconductor layer 13 can be effectively inhibited from occurring, and it is also possible to prevent a local battery from being formed. As a result, the second conductor layer 112 largely contributes to the enhancement of the incident photon-to-current conversion efficiency.

Furthermore, according to this embodiment, since the first conductor layer 111 and the second conductor layer 112 can be formed at a relatively low temperature, a resin film or the like with relatively-low heat resistance can be used for the transparent substrate 10.

### Second Embodiment

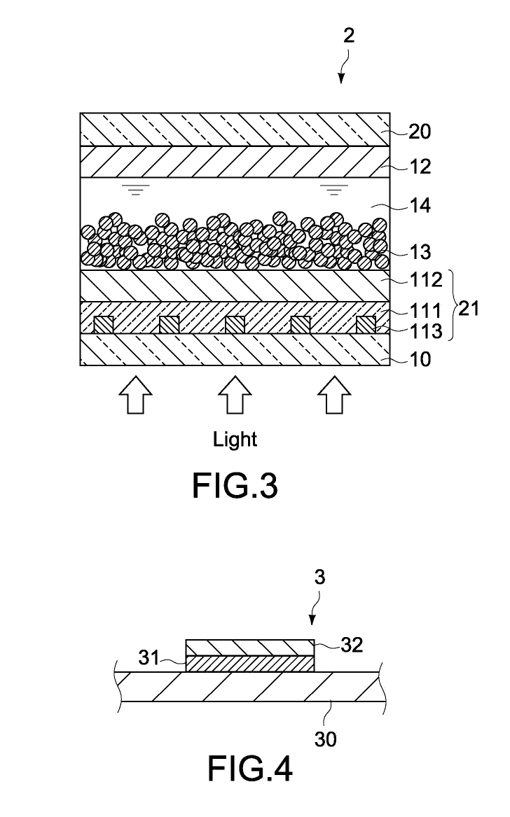

FIG. 3 is a schematic cross-sectional diagram of a photoelectric conversion element according to a second embodiment of the present invention. Portions that correspond to those of the first embodiment above in the figure are denoted by the same reference numerals, and detailed descriptions thereof will be omitted.

In a photoelectric conversion element 2 of this embodiment, a negative electrode 21 differs from that of the first embodiment and includes a multilayer structure constituted of the first conductor layer 111, the second conductor layer 112, and a third conductor layer 113. The third conductor layer 113 is provided inside the first conductor layer 111 and has a specific resistance (third specific resistance) smaller than that of the first conductor layer 111. Specifically, the third conductor layer 113 is constituted of a metal wiring of silver (Ag), an alloy thereof, and the like, though the metal type is not limited thereto. Alternatively, conductive materials other than metal may be used for the third conductor layer 113.

The third conductor layer 113 is formed in a lattice on the transparent substrate 10. The lattice includes stripes, a net-like shape, and meshes. The first conductor layer 111 is formed on the transparent substrate 10 so as to cover the third conductor layer 113, and the second conductor layer 112 is laminated on the first conductor layer 111.

According to this embodiment, since the third conductor layer 113 having a smaller specific resistance than the first conductor layer 111 is provided inside the first conductor layer 111, the resistance of the negative electrode 21 can be made low. As a result, the incident photon-to-current conversion efficiency can be additionally enhanced.

Furthermore, since the third conductor layer 113 is formed in a lattice, optical transparency of the negative electrode 21 can be maintained. A line width, pitch, thickness, and the like of the wiring constituting the third conductor layer 113 are not particularly limited.

Heretofore, the embodiments of the present invention have been described. However, the present invention is of course not limited to those embodiments and can be variously modified based on the technical idea of the present invention.

For example, although the above embodiments have described the examples in which the present invention is applied to the negative electrodes 11 and 21 of the photoelectric conversion elements 1 and 2, the present invention is not limited thereto and is also applicable to an electrode layer in a resistance-film-type touch panel, various wiring layers in a liquid crystal display and an organic EL display, and the like.

The present invention is also applicable to a wiring formed on a printed circuit board. FIG. 4 is a schematic cross-sectional diagram of a printed circuit board. A printed circuit board 3 shown in the figure includes a substrate 30, a first conductor layer 31, and a second conductor layer 32. The multilayer film constituted of the first conductor layer 31 and the second conductor layer 32 constitutes a wiring layer in the printed circuit board 3. The first conductor layer 31 is formed of, for example, ITO, and the second conductor layer 32 is formed of a transparent conducting oxide including, for example, a titanium oxide.

According to the printed circuit board 3 having the structure described above, a wiring layer having transparency, conductivity, and corrosion resistance can be formed. In addition, wiring patterns having a desired configuration can be easily formed by wet etching, laser etching, and the like.

The present application contains subject matter related to that disclosed in Japanese Priority Patent Application JP 2010-087549 filed in the Japan Patent Office on Apr. 6, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A transparent conductive film, comprising:
a first conductor layer formed of a first transparent conducting oxide having a first specific resistance; and
a second conductor layer that is laminated on the first conductor layer, has a second specific resistance that is equal to or larger than the first specific resistance and equal to or smaller than 1*10⁶ Ω*cm, and is formed of a second transparent conducting oxide including titanium.

2. The transparent conductive film according to claim 1,
wherein an increase of a sheet resistance with respect to a sheet resistance of the first conductor layer alone, which is obtained after the second conductor layer is laminated, is 10Ω/□ or less.

3. The transparent conductive film according to claim 2,
wherein the first transparent conducting oxide is a tin oxide including indium.

4. The transparent conductive film according to claim 1, further comprising
a third conductor layer that is provided inside the first conductor layer, has a third specific resistance smaller than the first specific resistance, and is formed in a lattice.

5. A photoelectric conversion element, comprising:
a first electrode including a first conductor layer formed of a first transparent conducting oxide having a first specific resistance, and a second conductor layer that is laminated on the first conductor layer, has a second specific resistance that is equal to or larger than the first specific resistance and equal to or smaller than 1*10⁶ Ω*cm, and is formed of a second transparent conducting oxide including titanium;
an oxide semiconductor layer that comes into contact with the second conductor layer and supports a photosensitization pigment;
a second electrode opposed to the oxide semiconductor layer; and
an electrolyte layer provided between the oxide semiconductor layer and the second electrode.

6. The photoelectric conversion element according to claim 5,
wherein the oxide semiconductor layer is formed of a porous titanium oxide.
